(19) United States
(12) Patent Application Publication
(10) Pub. No.: US 2026/0047474 A1
(43) Pub. Date: Feb. 12, 2026

(54) SEMICONDUCTOR PACKAGE AND METHOD OF MANUFACTURING THE SAME

(71) Applicant: Samsung Electronics Co., Ltd., Suwon-si (KR)

(72) Inventors: Chulho JUNG, Suwon-si (KR); Jihye SHIM, Suwon-si (KR)

(73) Assignee: Samsung Electronics Co., Ltd., Suwon-si (KR)

(21) Appl. No.: 19/279,186

(22) Filed: Jul. 24, 2025

(30) Foreign Application Priority Data
Aug. 7, 2024 (KR) 10-2024-0105477

(51) Int. Cl. H01L 23/00; H01L 23/31; H01L 25/065

(52) U.S. Cl. CPC H01L 24/29; H01L 23/3107; H01L 24/16; H01L 24/32; H01L 24/73; H01L 24/81; H01L 24/83; H01L 24/92; H01L 24/95; H01L 25/0657; H01L 2224/16148; H01L 2224/2919; H01L 2224/32058; H01L 2224/32145; H01L 2224/73104; H01L 2224/81191; H01L 2224/81203; H01L 2224/83031; H01L 2224/83191; H01L 2224/83862; H01L 2224/9211; H01L 2224/95001; H01L 2225/06513; H01L 2225/06541

(57) ABSTRACT

A semiconductor package comprises a base chip, a plurality of semiconductor chips sequentially stacked on the base chip, bump structures between the base chip and a lowermost semiconductor chip of the plurality of semiconductor chips, and between the plurality of semiconductor chips, adhesive layers surrounding the bump structures between the base chip and the lowermost semiconductor chip of the plurality of semiconductor chips and between the plurality of semiconductor chips. The adhesive layers have a width equal to or less than a width of each of the plurality of semiconductor chips in a direction parallel to an upper surface of the base chip. At least one of the adhesive layers comprises a polymer resin having a hydrophilic group, a photosensitive compound physically bonded to the polymer resin, and an ionic material crosslinking the polymer resin.

### CROSS-REFERENCE TO RELATED APPLICATION

This U.S. non-provisional application claims priority under 35 U.S.C. § 119 to Korean Patent Application No. 10-2024-0105477 filed on Aug. 7, 2024, in the Korean Intellectual Property Office, the disclosure of which is incorporated herein by reference in its entirety.

### BACKGROUND

Some example embodiments relate to a semiconductor package and a method of manufacturing the same.

As electronic devices become more lightweight and have higher performance, it may be beneficial to use a semiconductor package having a reduced size and high-performance. To implement miniaturization, lightness, high performance, and high reliability of a semiconductor package, semiconductor packages in which a plurality of semiconductor chips are vertically stacked may be used.

### SUMMARY

Some example embodiments are directed to a semiconductor package having an adhesive layer including a photosensitive compound and a method of manufacturing the same.

According to some example embodiments, a semiconductor package includes a base chip, a first semiconductor chip on the base chip, first bump structures between the base chip and the first semiconductor chip, and the first bump structures electrically connecting the base chip and the first semiconductor chip, a plurality of second semiconductor chips sequentially stacked on the first semiconductor chip, second bump structures between adjacent second semiconductor chips of the plurality of second semiconductor chips, and the second bump structures electrically connecting the adjacent second semiconductor chips to each other, and adhesive layers including a first adhesive layer surrounding the first bump structures between the base chip and the first semiconductor chip and second adhesive layers surrounding the second bump structures between the plurality of second semiconductor chips. The adhesive layers have a width equal to or less than a width of the first semiconductor chip and a width of each of the plurality of second semiconductor chips in a direction parallel to an upper surface of the base chip. At least one of the adhesive layers includes a positive photosensitive epoxy resin composition comprising a photosensitive compound.

According to some example embodiments, a semiconductor package includes a base chip, a plurality of semiconductor chips sequentially stacked on the base chip, bump structures between the base chip and a lowermost semiconductor chip of the plurality of semiconductor chips, and between the plurality of semiconductor chips, and adhesive layers surrounding the bump structures between the base chip and the lowermost semiconductor chip of the plurality of semiconductor chips and between the plurality of semiconductor chips. The adhesive layers have a width equal to or less than a width of each of the plurality of semiconductor chips in a direction parallel to an upper surface of the base chip. At least one of the adhesive layers includes a polymer resin having a hydrophilic group, a photosensitive compound physically bonded to the polymer resin, and an ionic material crosslinking the polymer resin.

According to some example embodiments, a semiconductor package includes a base chip, a first semiconductor chip on the base chip, first bump structures electrically connecting the base chip and the first semiconductor chip, first adhesive layers surrounding the first bump structures below the first semiconductor chip, a second semiconductor chip on the first semiconductor chip, second bump structures electrically connecting the first semiconductor chip and the second semiconductor chip, second adhesive layers surrounding the second bump structures below the second semiconductor chips and an encapsulant covering side surfaces of the first and second semiconductor chips and side surfaces of the first and second adhesive layers on the base chip. The side surfaces of the first and second semiconductor chips and side surfaces of the first and second adhesive layers are on a same plane. The first and second adhesive layers include a polymer resin, a photosensitive compound, and a curing agent. A curing temperature of each of the first and second adhesive layers has a melting point higher than a melting point of each of the first and second bump structures.

### BRIEF DESCRIPTION OF DRAWINGS

The above and other aspects, features, and advantages of the present disclosure will be more clearly understood from the following detailed description, taken in combination with the accompanying drawings.

FIG. 1 is a plan view illustrating a semiconductor package according to some example embodiments.

FIG. 2 is a cross-sectional view illustrating a semiconductor package taken along line I-I′ in FIG. 1.

FIG. 3 is an enlarged view of a portion of a semiconductor package of FIG. 2 according to some example embodiments.

FIGS. 4A, 4B, and 4C are enlarged views of the portion A of FIG. 2 of a semiconductor package according to some example embodiments.

FIG. 5A is a plan view illustrating a semiconductor package according to some example embodiments.

FIG. 5B is a cross-sectional view illustrating a semiconductor package taken along line II-II′ in FIG. 5A.

FIG. 6 is a cross-sectional view illustrating a semiconductor package according to some example embodiments.

FIG. 7 is a cross-sectional view illustrating a semiconductor package according to some example embodiments.

FIGS. 8, 9, 10, 11, 12, and 13 are cross-sectional view illustrating operations/processes in a method of manufacturing a semiconductor package according to some example embodiments.

### DETAILED DESCRIPTION

Hereinafter, embodiments of the present disclosure will be described as follows with reference to the accompanying drawings.

In the drawings, parts having no relationship with the description are omitted for clarity, and the same or similar constituent elements are indicated by the same reference numeral throughout the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

Hereinafter, the terms “lower portion” and “upper portion” are for convenience of description and do not limit the positional relationship.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element, value, and/or property is referred to as being the same as another element, value, and/or property, it should be understood that an element, value, and/or property is the same as another element, value, and/or property within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

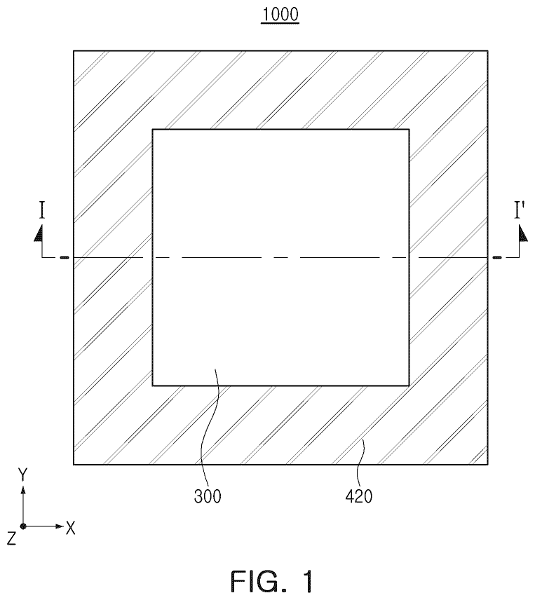

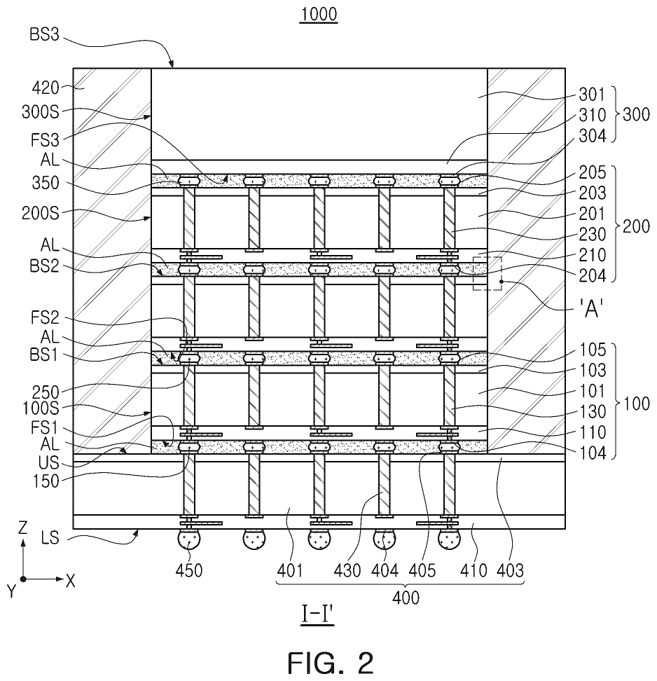

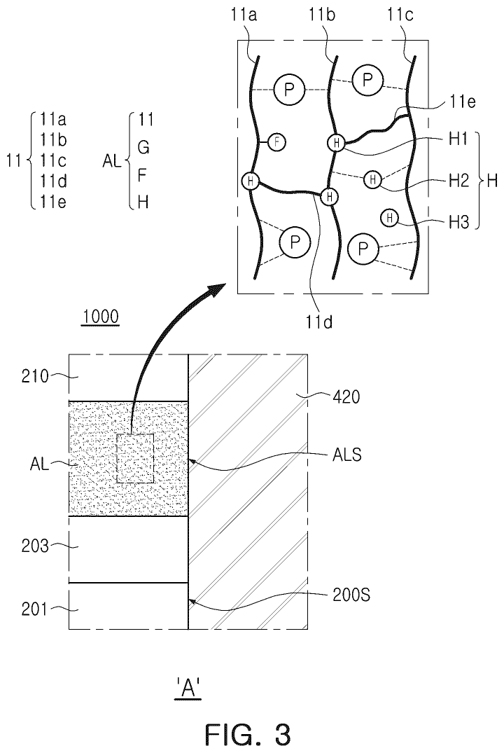

FIG. 1 is a plan view illustrating a semiconductor package according to some example embodiments. FIG. 2 is a cross-sectional view illustrating the semiconductor package taken along line I-I′ in FIG. 1. FIG. 3 is an enlarged view of a portion A in FIG. 2 of the semiconductor package according to some example embodiments.

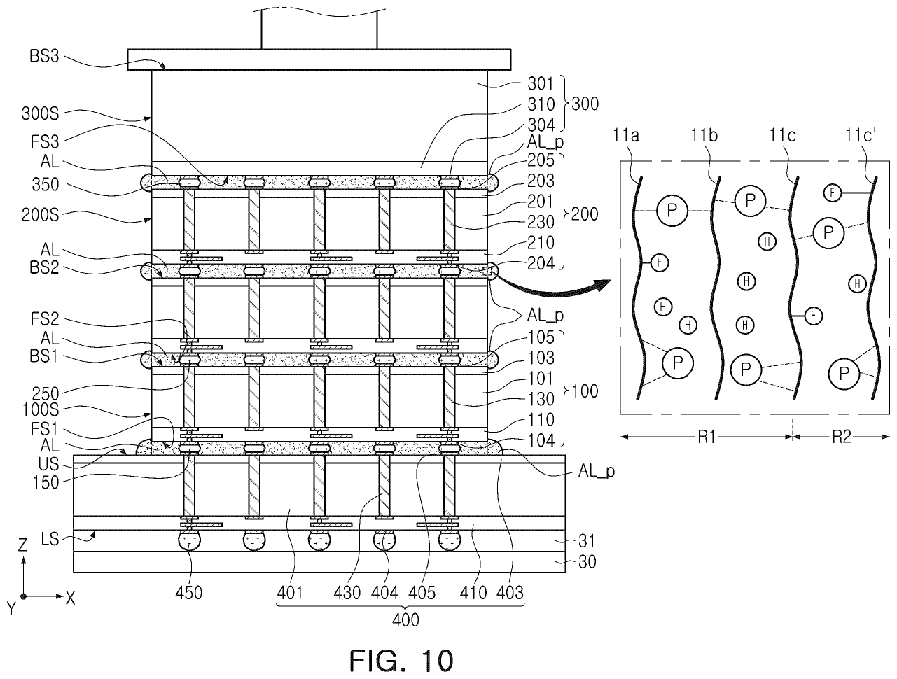

Referring to FIGS. 1 to 3, a semiconductor package 1000 in some example embodiments may include a plurality of semiconductor chips 100, 200, and 300, bump structures 150, 250, and 350, adhesive layers AL, and an encapsulant 420 on a base chip 400. In thermal compression bonding for stacking and fixing the plurality of semiconductor chips 100, 200, and 300 on the base chip 400, a fillet portion (“AL_p” in FIG. 10) of the adhesive layers AL may protrude beyond side surfaces of the plurality of semiconductor chips 100, 200, and 300.

According to some example embodiments, the adhesive layers AL may include a photosensitive compound P, such that, in the UV exposure process, a chemical structure of the photosensitive compound P of the fillet portion AL_p of the UV exposed region R2 may change (see FIG. 10). From another perspective, the adhesive layers AL including the photosensitive compound P may have characteristics of a positive photoresist. Accordingly, bonding between the polymer chain 11c′ and the photosensitive compound P′ of the fillet portion AL_p may be broken, such that solubility of the fillet portion AL_p may change.

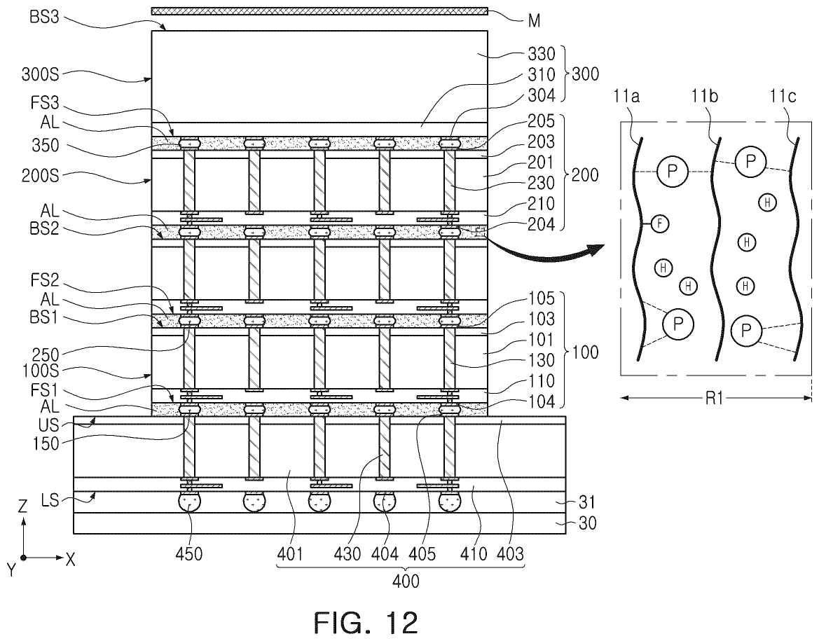

According to some example embodiments, the adhesive layers AL may further include a hydrophilic group F, and accordingly, in a subsequent developing process (e.g., FIG. 12), a developer may combine with the hydrophilic group F such that the fillet portion AL_p may be reduced or minimized (see FIG. 12).

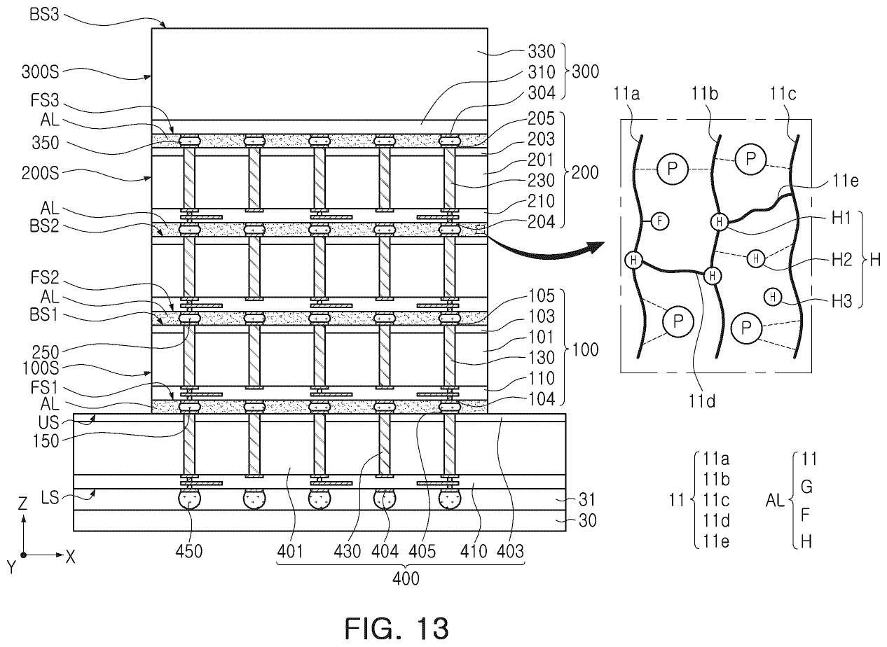

According to some example embodiments, the adhesive layers AL may further include a curing agent H, and accordingly, in a subsequent baking process (e.g., FIG. 13), polymer resin 11 of region R1 not exposed to UV may be crosslinked by the curing agent H. Consequently, the fillet portion of adhesive layers AL may be reduced or minimized, and a semiconductor package 1000 having improved reliability may be obtained.

Hereinafter, each component is described in greater detail with reference to the drawings.

The plurality of semiconductor chips 100, 200, and 300 may be configured as memory chips or memory devices configured to store or output data based on address commands and control commands transferred from the base chip 400. For example, the plurality of semiconductor chips 100, 200, and 300 may include volatile memory devices such as a DRAM or SRAM, or nonvolatile memory devices such as a PRAM, MRAM, FeRAM, or RRAM. An uppermost semiconductor chip 300 (hereinafter, referred to as the “third semiconductor chip”) among the plurality of semiconductor chips 100, 200, and 300 may not include a through via, and a back surface BS3 thereof may be exposed from the encapsulant 420, but example embodiments thereof are not limited thereto.

The plurality of semiconductor chips 100, 200, and 300 may include a stacked structure including a first semiconductor chip 100, at least one second semiconductor chip 200 (2 shown in FIG. 2), and a third semiconductor chip 300, stacked in order on a base chip 400.

The base chip 400 may include a substrate 401, an upper protective layer 403, an upper pad 405, and a lower pad 404, a device layer 410, and a through-electrode 430. The base chip 400 may be, for example, a buffer chip including a plurality of logic devices and/or memory devices in the device layer 410. Accordingly, the base chip 400 may transfer signals from the plurality of semiconductor chips 100, 200, and 300 stacked thereon to an external entity, device, or component, and may also transfer signals and power from an external entity, device, or component to the plurality of semiconductor chips 100, 200, and 300. The base chip 400 may perform both a logic function and a memory function through logic devices and memory devices, but in some example embodiments, the base chip 400 may include only logic devices and may perform only a logic function. Alternatively, in some example embodiments, the base chip 400 may include only memory devices and may perform only a memory function. In some example embodiments, the base chip 400 may perform other desired functions and may include corresponding devices.

The substrate 401 may include a semiconductor element, such as silicon or germanium (Ge), or a compound semiconductor, such as silicon carbide (SiC), gallium arsenide (GaAs), indium arsenide (InAs), or indium phosphide (InP). The substrate 401 may have a silicon on insulator (SOI) structure. The substrate 401 may include a conductive region, such as a well doped with impurities, or a structure doped with impurities. The substrate 401 may include various device isolation structures, such as a shallow trench isolation (STI) structure.

The upper protective layer 403 may be formed on an upper surface of the substrate 401 and may protect the substrate 401. The upper protective layer 403 may be or include an insulating layer such as a silicon oxide film, a silicon nitride film, or a silicon oxynitride film, but the material of the upper protective layer 403 is not limited to the above-mentioned materials. For example, the upper protective layer 403 may be or include a polymer such as polyimide (PI) or photosensitive polyimide (PSPI). In some example embodiments, a lower protective layer may be further formed on a lower surface of the device layer 410.

The upper pad 405 may be disposed on an upper surface US of the base chip 400 (or on an upper portion of the upper protective layer 403). The upper pad 405 may be or include, for example, at least one of aluminum (Al), copper (Cu), nickel (Ni), tungsten (W), platinum (Pt), and gold (Au). The lower pad 404 may be disposed on a lower surface LS of the base chip 400 (or on a lower portion of the device layer 410) and may be or include materials similar to those of the upper pad 405. However, the materials of the upper pad 405 and the lower pad 404 are not limited to the above-mentioned materials.

The device layer 410 may be disposed on a lower surface of the substrate 401 and may include different types of devices. For example, the device layer 410 may include various active elements and/or passive elements, such as FETs such as planar field effect transistor (FET) or FinFETs, memory devices such as a flash memory, dynamic random programmable read-only memory (EEPROM), phase-change random access memory (PRAM), magnetoresistive random access memory (MRAM), ferroelectric random access memory (FeRAM), and resistive random access memory (RRAM), logic elements such as AND, OR, and NOT, and various active and/or passive elements such as a system large scale integration (LSI), CMOS imaging sensor (CIS), and micro-electro-mechanical system (MEMS).

The device layer 410 may include an interlayer insulating layer and multiple wiring layers on the devices described above. The interlayer insulating layer may be or include silicon oxide or silicon nitride. The multiple wiring layers may be or include multiple wiring and/or vertical contacts. The multiple wiring layers may connect devices of the device layer 410 to each other, may connect devices to a conductive region of the substrate 401, and/or may connect devices to the lower pad 404.

The through-electrodes 430 may penetrate the substrate 401 in a vertical direction (Z-direction) and may provide an electrical path connecting the upper pad 405 to the lower pads 404. The through-electrodes 430 may be electrically connected to the plurality of semiconductor chips 100, 200, and 300. The through-electrodes 430 may include a conductive plug and a barrier film surrounding the conductive plug. The conductive plug may be or include a metal material, for example, tungsten (W), titanium (Ti), aluminum (AL), or copper (Cu). The conductive plug may be formed by a plating process, a PVD process, or a CVD process. The barrier film may include titanium (Ti), titanium nitride (TiN), tantalum (Ta), or tantalum nitride (TaN), and may be formed by a plating process, a PVD process, or a CVD process. In some example embodiments, a side insulating film including an insulating material such as silicon oxide, silicon nitride, or silicon oxynitride (e.g., high aspect ratio process (HARP) oxide) may be formed between side surfaces of the through-electrodes 430 and the substrate 401.

The connection bumps 450 may be disposed below the base chip 400. The connection bumps 450 may be electrically connected to the plurality of semiconductor chips 100, 200, and 300 through the through-electrodes 430. The connection bumps 450 may be or include, for example, tin (Sn) or an alloy including tin (Sn) (e.g., Sn—Ag—Cu). According to some example embodiments, the connection bumps 450 may have a combination of metal pillars and solder balls. The connection bumps 450 may be electrically connected to an external device such as a module substrate, a system board, or the like. The base chip 400 may have a width greater than a width of each of the plurality of semiconductor chips 100, 200, and 300 in the horizontal direction (the direction parallel to the upper surface US) (e.g., X and/or Y-direction). At least a portion of the connection bumps 450 and at least a portion of the lower pads 404 may be disposed at positions not overlapping the plurality of semiconductor chips 100, 200, and 300 in the vertical direction (Z-direction).

The first semiconductor chip 100 may be disposed on a base chip 400 and may include a first substrate 101, a first back surface protective layer 103, first front pads 104 disposed on a first front surface FS1, first back pads 105 disposed on a first back surface BS1, a first device layer 110, and first through vias 130 electrically connecting the first front pads 104 to the first back pads 105. The first substrate 101, the first back surface protective layer 103, the first back pads 105, the first front pads 104, the first device layer 110, and the first through vias 130 may be configured same as or similar to the substrate 401, the upper protective layer 403, the upper pad 405 and the lower pad 404, the device layer 410, and the through-electrodes 430 of the base chip 400 described above, respectively, and a detailed description thereof is omitted herein for the sake of brevity. The first semiconductor chip 100 may have the first front surface FS1 on which the first front pads 104 are disposed, a first back surface BS1 on which the first back pads 105 are disposed, and a first side surface 100S extending from an edge of the first front surface FS1 to an edge of the first back surface BS1.

The second semiconductor chip 200 may be disposed on the first semiconductor chip 100 and may include a second substrate 201, a second back surface protective layer 203, second front-surface pads 204 disposed on the second front surface FS2, second back-surface pads 205 disposed on the second back surface BS2, a second device layer 210, and second through vias 230 electrically connecting the second front-surface pads 204 to the second back-surface pads 205. The second substrate 201, the second back surface protective layer 203, the second front-surface pads 204, the second back-surface pads 205, the second device layer 210, and the second through vias 230 may be configured same as or similar to the substrate 401, the upper protective layer 403, the upper pad 405 and the lower pad 404, the device layer 410, and the through-electrodes 430 of the base chip 400 described above, respectively, and a detailed description thereof is omitted herein for the sake of brevity. According to some example embodiments, the second semiconductor chip 200 may be provided as a plurality of second semiconductor chips stacked in the vertical direction (Z-direction) on the first semiconductor chip 100.

The plurality of second semiconductor chips 200 may have the second front surface FS2 on which second front-surface pads 204 are disposed, a second back surface BS2 on which the second back-surface pads 205 is disposed, and a second side surface 200S extending from an edge of the second front surface FS2 to an edge of the second back surface BS2. The plurality of second semiconductor chips 200 may be electrically connected to each other through the second through vias 230 electrically connecting the second front-surface pads 204 to the second back-surface pads 205. In some example embodiments, a single second semiconductor chip 200 may be present or, in some example embodiments, the plurality of second semiconductor chips 200 may include three or more second semiconductor chips 200.

The third semiconductor chip 300 may be disposed on the second semiconductor chip 200 and may include a third substrate 301, third front-surface pads 304 disposed on the third front surface FS3, and a third device layer 310. The third substrate 301, the third front-surface pads 305, and the third device layer 310 may be configured same as or similar to the substrate 401, the lower pad 404, and the device layer 410 of the base chip 400 described above, respectively, and a detailed description thereof is omitted herein for the sake of brevity. The third semiconductor chip 300 may have a third front surface FS3 on which the third front-surface pads 304 is disposed, a third back surface BS3 disposed opposite to the third front-surface pads 304, and a third side surface 300S extending from an edge of the third front surface FS3 to an edge of the third back surface BS3. The third semiconductor chip 300 may be disposed on an uppermost side of the plurality of semiconductor chips 100, 200, and 300, and the third back surface BS3 may be exposed from the encapsulant 420. In other words, the third semiconductor chip 300 may be the topmost chip in the stacked structure including the plurality of semiconductor chips 100, 200, and 300. Also, the third semiconductor chip 300 may have a thickness greater than a thicknesses of each of the first semiconductor chip 100 and the plurality of second semiconductor chips 200.

The bump structures 150, 250, and 350 may be disposed between the plurality of semiconductor chips 100, 200, and 300. For example, the bump structures 150, 250, and 350 may include a first bump structure 150 disposed between the base chip 400 and the first front surface FS1 of the first semiconductor chip 100, a plurality of the second bump structures 250 disposed on the second front surface FS2 of each of the second semiconductor chips 200, and a third bump structure 350 disposed between the third front surface FS3 of the third semiconductor chip 300 and the second back surface BS2 of the uppermost second semiconductor chip 200. The bump structures 150, 250, and 350 may electrically connect pads which face each other to each other. The first bump structures 150 may electrically connect the upper pads 405 of the base chip 400 to the first front pads 104 of the first semiconductor chip 100. The second bump structures 250 may electrically connect the first back pads 105 of the first semiconductor chip 100 to the front-surface pads 204 of the second semiconductor chip 200 (or of the lowermost second semiconductor chip 200 of a plurality of second semiconductor chip 200), or the back-surface pads 205 to the front-surface pads 204 of the second semiconductor chips 200 between the lowermost and the uppermost second semiconductor chips 200. The third bump structures 350 may electrically connect the second back-surface pads 205 of the second semiconductor chip 200 (or of the uppermost second semiconductor chip 200 of the plurality of second semiconductor chips 200) to the third front-surface pads 304 of the third semiconductor chip 300. The bump structures 150, 250, and 350 may be or include, for example, tin (Sn), indium (In), bismuth (Bi), antimony (Sb), copper (Cu), silver (Ag), zinc (Zn), lead (Pb) and/or alloys thereof. The alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or the like.

The adhesive layers AL may surround bump structures 150, 250, and 350 disposed between the plurality of semiconductor chips 100, 200, and 300, and may affix or fasten the plurality of semiconductor chips 100, 200, and 300 on the base chip 400. The adhesive layers AL may be disposed on the first front surface FS1 of the first semiconductor chip 100, the second front surface FS2 of a plurality of second semiconductor chips 200, and the third front surface FS3 of the third semiconductor chip 300, respectively. The adhesive layers AL may include a first adhesive layer surrounding the first bump structures 150 below the first semiconductor chip 100, a second adhesive layer surrounding the second bump structures 250 below the second semiconductor chip 200, and a third adhesive layer surrounding the third bump structures 350 below the third semiconductor chip 300.

In some example embodiments, by removing a fillet portion of the adhesive layers AL protruding from an outer side (e.g., lateral side) of the plurality of semiconductor chips 100, 200, and 300, reliability of the semiconductor package 1000 may improve. Accordingly, the adhesive layers AL may have a width substantially equal to or smaller than a width of a first semiconductor chip 100, a width of each of the plurality of second semiconductor chips 200, and a width of the third semiconductor chip 300 in a direction parallel to the upper surface US of the base chip 400 (X- and Y-directions). Also, the adhesive layers AL may completely overlap the plurality of semiconductor chips 100, 200, and 300 in the vertical direction (Z-direction). A side surface ALS (FIG. 3) of the adhesive layers AL may be aligned (or flushed) with side surfaces 100S, 200S, and 300S of the plurality of semiconductor chips 100, 200, and 300, respectively, or may be disposed in the side surfaces 100S, 200S, and 300S of each.

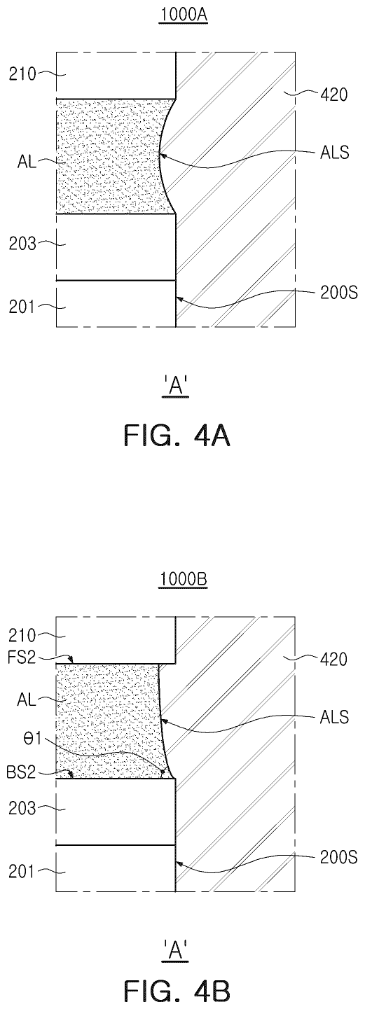

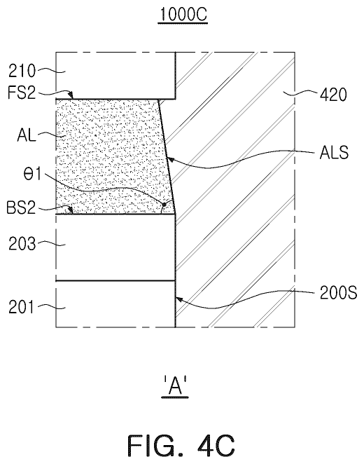

The first side surface 100S of the first semiconductor chip 100, the second side surface 200S of the second semiconductor chip 200, and the third side surface 300S of the third semiconductor chip 300 may be aligned with (e.g., vertically aligned with) the side surface ALS of the adhesive layers AL. From another perspective, the first side surface 100S of the first semiconductor chip 100, the second side surface 200S of the second semiconductor chip 200, and the third side surface 300S of the third semiconductor chip 300 may be on the same plane as the side surface ALS of the adhesive layers AL. In some example embodiments, at least one side surface ALS of the adhesive layer AL may not be aligned with the first side surface 100S, the second side surface 200S, and the third side surface 300S (see FIGS. 4A to 4C).

The adhesive layers AL may be configured as a non-conductive film (NCF), but example embodiments are not limited thereto, and, in some example embodiments, the adhesive layers AL may be or include any kind of polymer film usable in a thermocompression bonding process.

As illustrated in FIG. 3, the adhesive layers AL may include a polymer resin 11, for example, a thermosetting resin such as an epoxy resin. The polymer resin 11 may have a three-dimensional network structure by crosslinking between polymer backbones 11a, 11b, 11c, 11d, and 11e.

The polymer backbones 11a, 11b, 11c, 11d, and 11e may be crosslinked by a curing agent H. In some example embodiments, the curing agent H may be or include an ionic material having a first ion and a second ion. According to some example embodiments, the ionic material may be or include an ionic liquid. The first and second ions may be a positive ion and a negative ion, respectively.

The ionic material may be or include 1-butyl-3-methylimidazolium tetrafluoroborate, [BMIM][BF₄]), 1-ethyl-3-methyl-imidazolium dicyanamide, [EMIM][N(CN)₂]), 1-butyl-3-methylimidazolium tetrafluorophosphate, [BMIM][PF₄]), 1,3-dioctadecyl-methylimidazolium iodide, [DODIM][I]), 1-aminopropyl-3-butylimidazolium bistrifluoromethanesulfonate bis(trifluoromethanesulfonyl)imide, [APBIM][NTf₂]), tetrabutylammonium leucine, [N₄₄₄₄][Leu], or trihexyltetradecylphosphonium ethylhexanoyl, [THTP][EH], but example embodiments are not limited thereto.

In some example embodiments, at least a portion H1 of the ionic materials may directly react with the polymer backbones 11a, 11b, 11c, 11d, and 11e and may form a chemical bond. For example, a first ion of the ionic material H1 may directly react with the polymer backbones 11a, 11b, 11c, 11d, and 11e and may form a chemical bond during the curing process. Here, the first ion may be a positive ion. In some example embodiments, at least a portion H2 of the ionic materials may function as a physical crosslinker in the polymer matrix. The ionic material H2 may connect the polymer backbones (e.g., 11b and 11c) to each other, for example, through ionic interaction or non-covalent bonding. In some example embodiments, at least a portion H3 of the ionic materials may function as a crosslinker. The ionic material H3 may, for example, promote ring-opening polymerization of the epoxy group and may form crosslinks between the polymer backbones 11a, 11b, 11c, 11d, and 11e. In some example embodiments, bonding between the ionic material H3 and the polymer backbones 11a, 11b, 11c, 11d, and 11e may not be formed.

The curing temperature of the curing agent H in some example embodiments may be at least about 200° C. In some example embodiments, the curing temperature may be in a range of about 200° C. to about 300° C. In some example embodiments, the curing temperature may be in a range of about 250° C. to about 300° C.

The adhesive layers AL may further include a photosensitive compound P. When the photosensitive compound P is exposed to light, for example, ultraviolet light, a chemical structure of the photosensitive compound P may change such that solubility of the adhesive layers AL may change. In some example embodiments, the photosensitive compound P may be referred to as a photoactive compound (PAC). The adhesive layers AL including the photosensitive compound P may have characteristics of a positive photoresist. In some example embodiments, the adhesive layers AL may be referred to as a positive photosensitive insulating resin composition.

In some example embodiments, the photosensitive compound P may be or include an azo compound. The azo compound may include a diazo quinone compound. Here, the diazo quinone compound may include, for example, diazonaphthoquinone (DNQ), but example embodiments are not limited thereto.

In some example embodiments, the photosensitive compound P may be or include a diazide compound. The diazide compound may be or include a quinone diazide compound. The quinone diazide compound may be or include, for example, benzoquinone diazide, naphthoquinone diazide and derivatives thereof. The benzoquinone diazide may be or include 1,2-benzoquinonediazide, and the naphthoquinone diazide may be or include 1,2-naphthoquinonediazide, but example embodiments are not limited thereto. The derivative may include 1,2-benzoquinonediazide-4-sulfonic acid, 1,2-benzoquinonediazide-4-sulfonic acid ester, 1,2-naphthoquinonediazide-5-sulfonic acid, 1,2-naphthoquinonediazide-5-sulfonic acid ester, 1,2-naphthoquinonediazide-4-sulfonic acid, or 1,2-naphthoquinonediazide-4-sulfonic acid ester, but example embodiments are not limited thereto. The photosensitive compound P in some example embodiments may include at least one of an azo compound and/or a diazide compound.

The photosensitive compound P may be physically or non-chemically coupled to the polymer resin 11. The photosensitive compound P may be coupled to a single polymer backbone (e.g., each of 11a and 11c), and/or may couple a plurality of polymer backbones (e.g., 11a to 11b, and 11b to 11c) to each other, for example, by van der Waals force or hydrogen bonding.

The adhesive layers AL may further include a functional group F. The functional group F may include a hydrophilic group. The hydrophilic group may be or include at least one of, for example, a hydroxyl group, a carboxyl group, or an amine group, but example embodiments are not limited thereto. The functional group F, the curing agent H, and the photosensitive compound P of the adhesive layers AL in some example embodiments may be detected by a technique such as Raman spectroscopy, nuclear magnetic resonance (NMR), or infrared spectroscopy (IR).

Each of the adhesive layers AL may have a thickness of 50 μm (or about 50 μm) or less. A thickness of each of the adhesive layers AL may range, for example, from 1 μm (or about 1 μm) to 50 μm (or about 50 μm).

The encapsulant 420 may encapsulate the plurality of semiconductor chips 100, 200, and 300 that are affixed to the base chip 400. The encapsulant 420 may be formed to expose the back surface BS3 of the third semiconductor chip 300. According to some example embodiments, the encapsulant 420 may also be formed to cover the back surface BS3 of the third semiconductor chip 300. The encapsulant 420 may be formed of an insulating material such as, for example, epoxy mold compound (EMC), but the material of the encapsulant 420 is not limited to any particular material. The encapsulant 420 may surround side surfaces of the plurality of semiconductor chips 100, 200, and 300. The encapsulant 420 may be in direct contact with the side surfaces 100S, 200S, and 300S of the plurality of semiconductor chips 100, 200, and 300 and the side surface 410S of the adhesive layers AL. According to some example embodiments, a heat dissipation structure may be disposed on an upper portion of the encapsulant 420. The heat dissipation structure may limit, reduce, or otherwise control warpage of the semiconductor package 1000 and may dissipate heat generated from the plurality of semiconductor chips 100, 200, and 300 to an external entity or component, such as a heat sink or radiator, or may dissipate the heat to the external environment.

FIGS. 4A to 4C are enlarged views illustrating the portion A of FIG. 2 of a semiconductor package according to some example embodiments.

Referring to FIG. 4A, in a semiconductor package 1000A, at least one side surface ALS of the adhesive layer AL may be a curved surface. For example, the side surface ALS of the adhesive layer AL may be an inwardly concave curved surface. For example, the side surface of the first adhesive layer surrounding the first bump structures 150 may have a relatively more inwardly curved surface than the side surface 100S of the first semiconductor chip 100. Additionally or alternatively, the side surface of the second adhesive layer surrounding the second bump structures 250 may have a relatively more inwardly curved surface than the side surface 200S of the second semiconductor chip 2100. Additionally or alternatively, the side surface of the third adhesive layer surrounding the third bump structures 350 may have a relatively more inwardly curved surface than the side surface 300S of the third semiconductor chip 300.

Referring to FIG. 4B, in a semiconductor package 1000B, a width of at least one adhesive layer AL in the horizontal direction (e.g., X-direction) may increase toward the back surface BS1 and BS2 of the semiconductor chips (e.g., 100 and 200) or the upper surface US of the base chip 400. As illustrated, an upper portion of the side surface ALS of the adhesive layer AL may be spaced inward from the side surfaces (e.g., side surfaces 100S or 200s) of the semiconductor chips 100 or 200 and the lower portion of the side surface ALS of the adhesive layer AL may be proximate or contact the side surfaces of the semiconductor chips 100 or 200. In some example embodiment, the side surface ALS of at least one adhesive layer AL may have a curved surface or an inclined curved surface.

A width of at least one adhesive layer AL in the horizontal direction and between adjacent second semiconductor chips 200 may increase in a direction away from the second front surface FS2 of the second semiconductor chip on an upper side and toward the second back surface BS2 of the second semiconductor chip on a lower side. The first angle θ1 between the side surface ALS of the adhesive layer AL and the second back surface BS2 of the second semiconductor chip on the lower side may be about 90° or less.

Similarly, between the first semiconductor chip 100 and the base chip 400, a horizontal width of the adhesive layer AL may increase in a direction away from the first front surface FS1 of the first semiconductor chip 100 and toward an upper surface US of the base chip 400 on a lower side. Similarly, between the third semiconductor chip 300 and the uppermost second semiconductor chip 200, a horizontal width of the adhesive layer AL may increase in a direction away from the third front surface FS3 of the third semiconductor chip 300 and toward the second back surface BS2 of the second semiconductor chip 200 on an uppermost side.

Referring to FIG. 4C, in a semiconductor package 1000C, a width of at least one adhesive layer AL in the horizontal direction (e.g., X-direction) may increase toward the back surface BS1 and BS2 of the semiconductor chips (e.g., 100, 200) or the upper surface US of the base chip 400. As compared to FIG. 4B, the side surface ALS of at least one adhesive layer AL may have a relatively flat or planar inclined surface.

Among the plurality of second semiconductor chips 200, a width of at least one adhesive layer AL in the horizontal direction may increase in a direction away from the second front surface FS2 of the second semiconductor chip 200 on an upper side and toward the second back surface BS2 of the second semiconductor chip 200 on a lower side. A first angle θ1 between the side surface ALS of the adhesive layer AL and the second back surface BS2 of the second semiconductor chip 200 on the lower side may be about 90° or less.

Similarly, between the first semiconductor chip 100 and base chip 400, a horizontal width of the adhesive layer AL may increase in a direction away from the first front surface FS1 of the first semiconductor chip 100 and toward the upper surface US of the base chip 400 of the lower side. Similarly, between the third semiconductor chip 300 and the uppermost second semiconductor chip 200, a horizontal width of the adhesive layer AL may increase in a direction away from the third front surface FS3 of the third semiconductor chip 300 and toward the second back surface BS2 of the second semiconductor chip 200 on the uppermost side.

As such, in some example embodiments, the side surfaces ALS of the adhesive layers AL may not be aligned with the side surfaces 100S, 200S, and 300S of the plurality of semiconductor chips 100, 200, and 300, and a fillet portion protruding outwardly than the side surfaces 100S, 200S, and 300S of the plurality of semiconductor chips 100, 200, and 300 may not be formed.

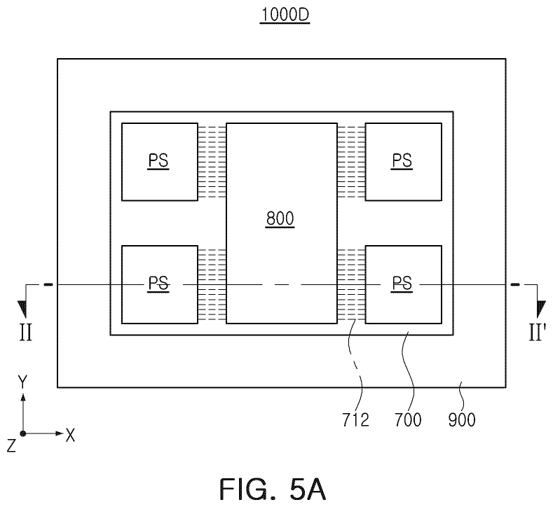

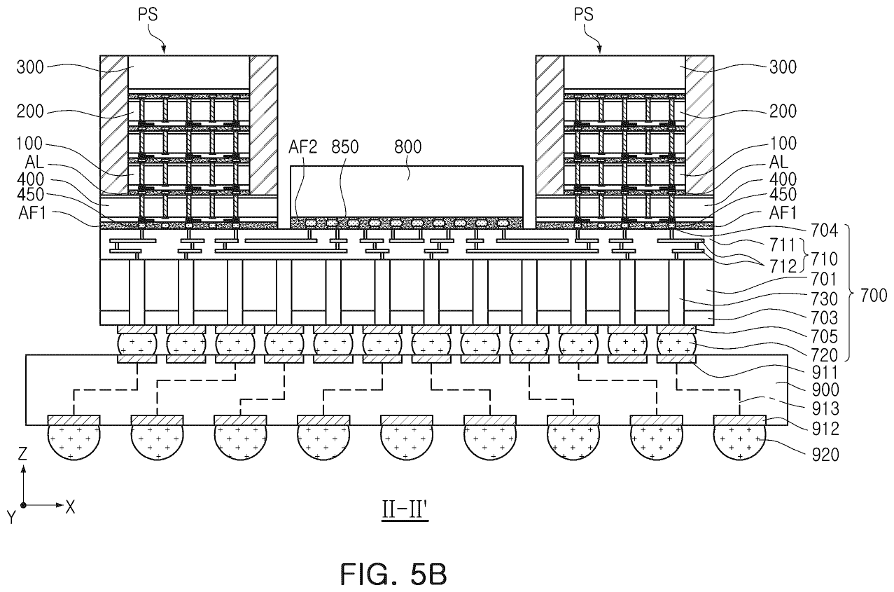

FIG. 5A is a plan view illustrating a semiconductor package according to some example embodiments. FIG. 5B is a cross-sectional view illustrating a semiconductor package taken along line II-II′ in FIG. 5A.

Referring to FIGS. 5A and 5B, a semiconductor package 1000D in some example embodiments may include a package substrate 900, an interposer substrate 700, at least one chip structure PS, and a processor chip 800. The chip structure PS may be configured same as or similar to the semiconductor packages 1000, 1000A, 1000B, and 1000C described with reference to FIGS. 1 to 4C.

The package substrate 900 may be configured as a support substrate on which the interposer substrate 700, the processor chip 800, and the chip structure PS are mounted, and may be configured as a substrate for a semiconductor package including a printed circuit board (PCB), a ceramic substrate, a glass substrate, a tape wiring substrate, or the like. The body of the package substrate 900 may include different materials depending on the type of the substrate. For example, when the package substrate 900 is configured as a printed circuit board, the package substrate 900 may be in the form of a body copper-clad laminate or a wiring layer may be further stacked on one end surface or both surfaces of the copper-clad laminate.

The package substrate 900 may include a lower terminal 912, an upper terminal 911, and a redistribution circuit 913. The upper terminal 911, the lower terminal 912, and the redistribution circuit 913 may form an electrical path connecting a lower surface to the upper surface of the package substrate 900. The upper terminal 911, the lower terminal 912, and the redistribution circuit 913 may be or include a metal material, for example, at least one metal selected from a group consisting of copper (Cu), aluminum (AL), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy including two or more metals. An external connection terminal 920 connected to the lower terminal 912 may be disposed on a lower surface of the package substrate 900. The external connection terminal 920 may be or include tin (Sn), indium (In), bismuth (Bi), antimony (Sb), copper (Cu), silver (Ag), zinc (Zn), lead (Pb) and/or an alloy thereof.

The interposer substrate 700 may include a substrate 701, a lower protective layer 703, a lower pad 705, an interconnection structure 710, a metal bump 720, and a through via 730. The chip structure PS and the processor chip 800 may be electrically connected to each other through the interposer substrate 700.

The substrate 701 may be formed of, for example, any one of a silicon, an organic, a plastic, and a glass substrate. When the substrate 701 is configured as a silicon substrate, the interposer substrate 700 may be referred to as a silicon interposer. When the substrate 701 is configured as an organic substrate, the interposer substrate 700 may be referred to as a panel interposer.

The lower protective layer 703 may be disposed on a lower surface of the substrate 701, and the lower pad 705 may be disposed below the lower protective layer 703. The lower pad 705 may be connected to the through via 730. The chip structure PS and the processor chip 800 may be electrically connected to the package substrate 900 through the metal bumps 720 disposed below the lower pad 705.

The interconnection structure 710 may be disposed on an upper surface of the substrate 701 and may include an interlayer insulating layer 711 and a single-layer wiring structure 712 or multiple-layer wiring structure 712. When the interconnection structure 710 includes a multiple-layer wiring structure, wiring patterns of different layers may be connected to each other through contact vias.

The through via 730 may extend from an upper surface of the substrate 701 to a lower surface and penetrate the substrate 701. Also, the through via 730 may extend into the interconnection structure 710 and may be electrically connected to wirings of the interconnection structure 710. When the substrate 701 is silicon, the through via 730 may be referred to as a TSV. In some example embodiments, the interposer substrate 700 may include a wiring structure therein and may not include a through via.

The interposer substrate 700 may be used for converting or transferring an input electrical signal between the package substrate 900 and the chip structure PS or the processor chip 800. Accordingly, the interposer substrate 700 may not include devices such as active or passive elements. In some example embodiments, the interconnection structure 710 may be disposed in a lower portion of the through via 730. For example, the position relationship between the interconnection structure 710 and the through via 730 may be relative.

The metal bump 720 may electrically connect the interposer substrate 700 to the package substrate 900. The chip structure PS may be electrically connected to the metal bumps 720 through wirings of the interconnection structure 710 and the through vias 730. According to some example embodiments, the lower pads 705 used for power or ground may be integrated and may be connected together to the metal bumps 720, such that the number of lower pads 705 may be more than the number of metal bumps 720.

The processor chip 800 may include, for example, a central processor (CPU), a graphics processor (GPU), a field programmable gate array (FPGA), a digital signal processor (DSP), an encryption processor, a microprocessor, a microcontroller, an analog-to-digital converter, an application-specific integrated circuit (ASIC), or the like. Connection bumps 850 may be disposed below the processor chip 800.

At least one chip structure PS and the processor chip 800 may be attached to the interposer substrate 700 by adhesive layers AF1 and AF2. The adhesive layers AF1 and AF2 may be same as or similar to the adhesive layers AL described with reference to FIGS. 1 to 4C, and a detailed description thereof is omitted therein.

The adhesive layer AF1 may surround the connection bumps 450 and may affix or fasten the chip structure PS to the interposer substrate 700. The adhesive layer AF1 may be disposed between a lower surface (e.g., “LS” in FIG. 2) of the chip structure PS and an upper surface of the interposer substrate 700. The adhesive layer AF2 may surround the connection bumps 850 and may affix or fasten the processor chip 800 to the interposer substrate 700. The adhesive layer AF2 may be disposed between the lower surface of the processor chip 800 and the upper surface of the interposer substrate 700.

According to some example embodiments, the semiconductor package 1000D may further include an internal sealing material covering the chip structure PS and the processor chip 800 on the interposer substrate 700. Also, the semiconductor package 1000D may further include an external sealing material covering the interposer substrate 700 and an internal sealing material on the package substrate 900. The external sealing material and the internal sealing material may be formed together and may be same as or similar to each other. In some example embodiments, the semiconductor package 1000D may further include a heat dissipation structure covering the chip structure PS and the processor chip 800.

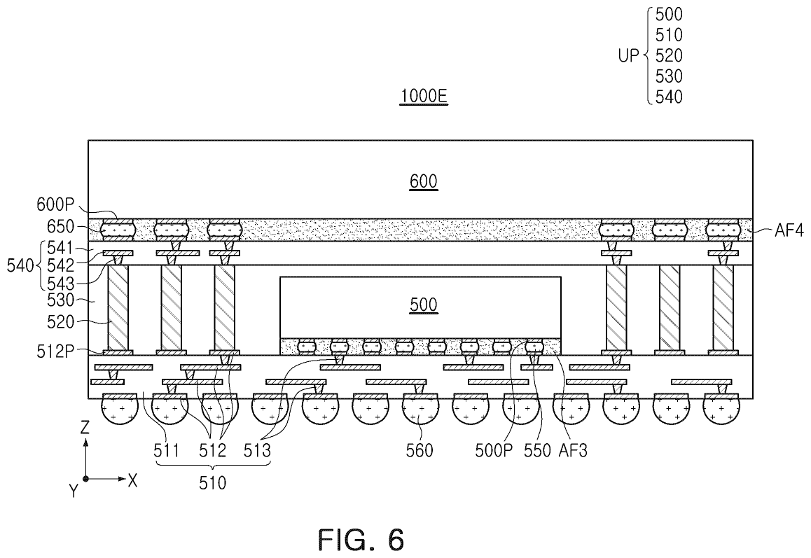

FIG. 6 is a cross-sectional view illustrating a semiconductor package according to some example embodiments.

Referring to FIG. 6, a semiconductor package 1000E may include a unit package structure UP and an upper chip structure 600. The unit package structure UP may include a lower chip structure 500, a lower redistribution structure 510, a plurality of posts 520, an encapsulant 530, and an upper redistribution structure 540.

The lower chip structure 500 may include connection terminals 500P disposed on the lower redistribution structure 510 and electrically connected to the lower redistribution layer 512. The connection terminals 500P may be connected to the lower redistribution layer 512 through lower connection bumps 550 disposed between the lower chip structure 500 and the lower redistribution structure 510. An adhesive layer AF3 surrounding the lower connection bumps 550 may be disposed below the lower chip structure 500. The adhesive layer AF3 may affix or fasten the lower chip structure 500 to the lower redistribution structure 510. The adhesive layer AF3 may be disposed between a lower surface of the lower chip structure 500 and an upper surface of the lower redistribution structure 510. The adhesive layer AF3 may be same as or similar to the adhesive layers AL described with reference to FIGS. 1 to 4C, and a detailed description thereof is omitted herein.

The upper chip structure 600 may be disposed on the upper redistribution structure 540. The upper chip structure 600 may be electrically connected to the lower redistribution layer 512 through the upper redistribution layer 542 and a plurality of posts 520. The upper chip structure 600 may include connection terminals 600P electrically connected to the upper redistribution layer 542. The connection terminals 600P may be connected to the plurality of posts 520 through upper connection bumps 650 disposed between the upper chip structure 600 and the upper redistribution structure 540. An adhesive layer AF4 surrounding the upper connection bumps 650 may be disposed below the upper chip structure 600. The adhesive layer AF4 may affix or fasten the upper chip structure 600 to the upper redistribution structure 540. The adhesive layer AF4 may be disposed between a lower surface of the upper chip structure 600 and an upper surface of the upper redistribution structure 540. The adhesive layer AF4 may be same as or similar to the adhesive layers AL described with reference to FIGS. 1 to 4C, and a detailed description thereof is omitted herein.

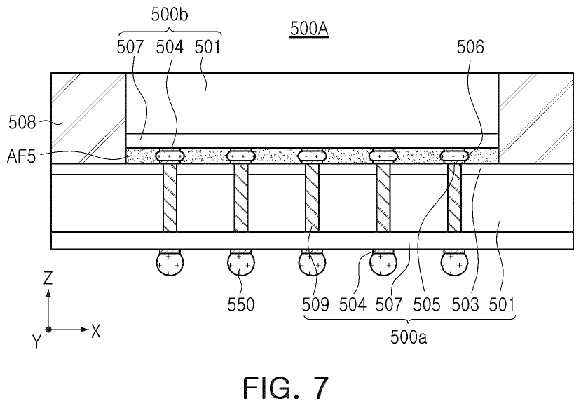

The lower chip structure 500 and the upper chip structure 600 may include a semiconductor wafer and a semiconductor wafer integrated circuit (IC) formed of a semiconductor element such as silicon, germanium, or a compound semiconductor such as silicon carbide (SiC), gallium arsenide (GaAs), indium arsenide (InAs), and indium phosphide (InP). The lower chip structure 500 and the upper chip structure 600 may be configured as a bare semiconductor chip without separate bumps or wiring layers formed therein, but example embodiments are not limited thereto, and the structures may also be configured as packaged type semiconductor chips. The integrated circuit may be implemented as a logic circuit (or “logic chip”) including a central processor (CPU), a graphics processor (GPU), a field programmable gate array (FPGA), an application processor (AP), a digital signal processor, an encryption processor, a microprocessor, a microcontroller, an analog-to-digital converter, an application-specific IC (ASIC), or the like, or a memory circuit (or “memory chip”) including nonvolatile memory such as a volatile memory such as dynamic RAM (DRAM), static RAM (SRAM), and nonvolatile memory such as magnetic RAM (MRAM), resistive RAM (RRAM), and flash memory, or the like. The lower chip structure 500 and the upper chip structure 600 may include different types of semiconductor chips. For example, the lower chip structure 500 may include at least one logic chip, and the upper chip structure 600 may include at least one memory chip. According to some example embodiments, each of the lower chip structure 500 and the upper chip structure 600 may be configured as a package structure including a plurality of semiconductor chips, which will be described with reference to FIG. 7 below.

The lower redistribution structure 510 may be configured as a support substrate on which the lower chip structure 500 is mounted, and may include a lower insulating layer 511, lower redistribution layers 512, and a lower redistribution via 513.

The lower insulating layer 511 may be or include an insulating resin. The insulating resin may include a thermosetting resin such as an epoxy resin, a thermoplastic resin such as a polyimide, or a resin impregnated with an inorganic filler, for example, a prepreg, Ajinomoto build-up film (ABF), FR-4, or bismaleimide-triazine (BT). For example, the lower insulating layer 311 may include a photosensitive resin such as photo-imageable dielectric (PID). The lower insulating layer 511 may be or include a plurality of insulating layers stacked in the vertical direction (Z-axis direction). Depending on processes and/or design, boundaries between the plurality of insulating layers may be indistinct and adjacent insulating layers may merge with each other.

The lower redistribution layer 512 may be disposed on or in the lower insulating layer 511 and may redistribute the connection terminal 500P of the lower chip structure 500. The lower redistribution layer 512 may be or include a metal including, for example, copper (Cu), aluminum (AL), silver (Ag), tin (Sn), gold (Au), nickel (Ni), lead (Pb), titanium (Ti), or an alloy thereof. The lower redistribution layer 512 may perform various functions depending on a design. For example, the lower redistribution layer 512 may include a ground pattern, a power pattern, and a signal pattern. Here, the signal pattern may provide a transmission path for various signals, for example, a data signal other than the ground pattern, the power pattern, or the like. The lower redistribution layer 512 may include more or fewer number of redistribution layers than the number of redistribution layers illustrated in FIG. 6. The lower redistribution layer 512 may include redistribution pads 512P disposed on an upper surface of the lower redistribution structure 510. The redistribution pads 512P may be electrically connected to a plurality of posts 520 and connection terminals 500P of the lower chip structure 500.

The lower redistribution via 513 may extend vertically in the lower insulating layer 511 and may be electrically connected to the lower redistribution layer 512. For example, the lower redistribution via 513 may interconnect lower redistribution layers 512 at different levels. The lower redistribution via 513 may include a signal via, a ground via, and/or a power via. The lower redistribution via 513 may be or include a metal material, for example, copper (Cu), aluminum (AL), silver (Ag), tin (Sn), gold (Au), nickel (Ni), lead (Pb), titanium (Ti), or an alloy thereof. The lower redistribution via 513 may be a filled via in which the metal material is filled in the via hole or a conformal via in which the metal material extends along an internal wall of the via hole.

The external connection bumps 560 may be disposed below the lower redistribution structure 510. The external connection bumps 560 may be electrically connected to the lower redistribution layer 512. The semiconductor package 1000E may be connected to an external device, such as a module substrate, a system board, or the like, through the external connection bumps 560. The external connection bumps 560 may have a form in which a pillar (or under-bump metal) and a ball is combined. The pillar may include copper (Cu) or an alloy of copper (Cu), and the ball may include a low melting point metal, for example, tin (Sn) or an alloy including tin (Sn—Ag—Cu). According to some example embodiments, the external connection bumps 560 may include the pillar or the ball. According to some example embodiments, a resist layer protecting the external connection bumps 560 from physical and chemical damages may be formed on a lower surface of the lower redistribution structure 510.

At least one passive element may be disposed below the lower redistribution structure 510. The passive element may include, for example, a capacitor, an inductor, beads, or the like. The passive element may be flip-chip bonded to a lower surface of the lower redistribution structure 510. The passive element may be electrically connected to the lower redistribution layer 512 through a solder bump, or the like. An underfill resin may be filled between the passive element and the lower redistribution structure 510.

A plurality of posts 520 may penetrate the encapsulant 530 and may electrically connect the lower redistribution layer 512 to the upper redistribution layer 542. The plurality of posts 520 may be or include copper (Cu), nickel (Ni), titanium (Ti), lead (Pb), aluminum (AL), silver (Ag), gold (Au), platinum (Pt), or an alloy thereof. The plurality of posts 520 may extend in the vertical direction (Z-direction) in the encapsulant 530. The plurality of posts 520 may have a cylindrical or column shape, but example embodiments are not limited thereto.

The encapsulant 530 may cover at least a portion of each of the lower chip structure 500 and the plurality of posts 520. The encapsulant 530 may cover a side surface of each of the lower chip structure 500 and the plurality of posts 520. The encapsulant 530 may expose an upper surface of each of the plurality of posts 520. According to some example embodiments, the encapsulant 530 may expose an upper surface of the lower chip structure 500. The upper surface of the encapsulant 530 may be disposed on substantially the same plane as the upper surface of the lower chip structure 500 and the upper surfaces of the plurality of posts 520. The encapsulant 530 may be or include, for example, a thermosetting resin such as an epoxy resin, a thermoplastic resin such as a polyimide, or a prepreg, ABF, FR-4, BT, epoxy molding compound (EMC). For example, the encapsulant 530 may include EMC.

The upper redistribution structure 540 may be disposed on the encapsulant 530 and may include an upper insulating layer 541, upper redistribution layers 542, and an upper redistribution via 543.

The upper insulating layer 541 may be or include a thermosetting resin such as an epoxy resin, a thermoplastic resin such as a polyimide, or a resin impregnated with an inorganic filler, for example, a prepreg, Ajinomoto build-up film (ABF), FR-4, or bismaleimide-triazine (BT). For example, the upper insulating layer 541 may be or include a photosensitive resin such as PID. The upper insulating layer 541 may be or include a plurality of insulating layers stacked in the vertical direction (Z-direction). Depending on processes and/or design, boundaries between the plurality of insulating layers may be indistinct and adjacent insulating layers may merge with each other.

The upper redistribution layer 542 may be disposed on or in the upper insulating layer 541, and may redistribute the connection terminal 600P of the upper chip structure 600. The upper redistribution layer 542 may be or include a metal, for example, copper (Cu), aluminum (AL), silver (Ag), tin (Sn), gold (Au), nickel (Ni), lead (Pb), titanium (Ti), or an alloy thereof. The upper redistribution layer 542 may perform various functions depending on application and/or design. The upper redistribution layer 542 may include more or less number of redistribution layers than the number of redistribution layers illustrated in FIG. 6

The upper redistribution via 543 may extend vertically in the upper insulating layer 541 and may be electrically connected to the upper redistribution layer 542. For example, the upper redistribution via 543 may interconnect the upper redistribution layers 542 disposed on different levels. The upper redistribution via 543 may be or include a metal material, for example, copper (Cu), aluminum (AL), silver (Ag), tin (Sn), gold (Au), nickel (Ni), lead (Pb), titanium (Ti), or an alloy thereof. The upper redistribution via 543 may be a filled via in which the metal material is filled in the via hole or a conformal via in which the metal material extends along an internal wall of the via hole.

FIG. 7 is a cross-sectional view illustrating a semiconductor package according to some example embodiments, illustrating a lower chip structure 500 applicable to a semiconductor package 1000E in FIG. 6.

Referring to FIG. 7, a semiconductor package 500A may include a plurality of semiconductor chips 500a and 500b stacked vertically (Z-direction). At least one of the plurality of semiconductor chips 500a and 500b (e.g., semiconductor chip 500a in FIG. 7) may include through vias 509 electrically connecting the plurality of semiconductor chips 500a and 500b to each other. The plurality of semiconductor chips 500a and 500b may be configured as chiplets included in a multi-chip module (MCM). The plurality of semiconductor chips 500a and 500b may include a central processor (CPU), a graphics processor (GPU), a field programmable gate array (FPGA), a digital signal processor (DSP), an encryption processor, a microprocessor, a microcontroller, an analog-to-digital converter, an application-specific integrated circuit (ASIC), a volatile memory, a non-volatile memory, an input/output (I/O) circuit, an analog circuit, a serial-to-parallel conversion circuit, or the like.

The semiconductor package 500A may include the first semiconductor chip 500a and the second semiconductor chip 500b. The first semiconductor chip 500a may include a processor circuit, and the second semiconductor chip 500b may include at least one of an input/output circuit, an analog circuit, a memory circuit, and a serial-to-parallel conversion circuits for the processor circuit. The number of semiconductor chips 500a and 500b is not limited to 2 as illustrated in FIG. 7 and semiconductor package 500A may include more than 2 semiconductor chips. According to some example embodiments, the semiconductor package 500A may further include a molding member 508 covering at least a portion of each of the first semiconductor chip 500a and the second semiconductor chip 500b.

The first semiconductor chip 500a and the second semiconductor chip 500b may include a substrate 501, an upper protective layer 503, an upper pad 505, a circuit layer 507, a lower pad 504, and/or a through via 509. The substrate 501 may be or include a semiconductor element, such as silicon or germanium (Ge), or a compound semiconductor, such as silicon carbide (SiC), gallium arsenide (GaAs), indium arsenide (InAs), or indium phosphide (InP). The substrate 501 may have a silicon on insulator (SOI) structure. The substrate 501 may have a conductive region, such as a well doped with impurities, or an active surface and an opposite inactive surface doped with impurities. The substrate 501 may include various device isolation structures, such as a shallow trench isolation (STI) structure.

The upper protective layer 503 may be formed on an inactive surface of the substrate 501 and may protect the substrate 501. The upper protective layer 503 may be formed of an insulating layer such as a silicon oxide film, a silicon nitride film, or a silicon oxynitride film, but the material of the upper protective layer 503 is not limited thereto. For example, the upper protective layer 503 may be formed of a polymer such as PI Polyimide. A lower protective layer may be formed on a lower surface of the circuit layer 507.

The upper pad 505 may be disposed on the upper protective layer 503. The upper pad 505 may include, for example, at least one of aluminum (Al), copper (Cu), nickel (Ni), tungsten (W), platinum (Pt), and gold (Au). The lower pad 504 may be disposed on a lower portion of the circuit layer 507 and may include a material similar to the upper pad 505. However, the materials of the upper pad 505 and the lower pad 504 are not limited to the above-mentioned materials.

The circuit layer 507 may be disposed on an active surface of the substrate 501 and may include different types of devices. For example, the circuit layer 507 may include various active devices and/or passive elements, such as FETs such as a planar field effect transistor (FET) or FinFETs, memory devices such as a flash memory, dynamic random programmable read-only memory (EEPROM), phase-change random access memory (PRAM), magnetoresistive random access memory (MRAM), ferroelectric random access memory (FeRAM), and resistive random access memory (RRAM), logic elements such as AND, OR, and NOT, and various active and/or passive elements such as a system large scale integration (LSI), CMOS imaging sensor (CIS), and micro-electro-mechanical system (MEMS). The circuit layer 507 may include a wiring structure electrically connected to the devices described above and an interlayer insulating layer surrounding the wiring structure. The interlayer insulating layer may be or include silicon oxide or silicon nitride. The wiring structure may include multiple wiring and/or vertical contacts. The wiring structure may connect devices of the circuit layer 507 to each other, may connect devices to conductive regions of the substrate 501, or may connect devices to through vias 509.

The through vias 509 may penetrate the substrate 501 in the vertical direction (Z-direction) and may provide an electrical path connecting the upper pads 505 to the lower pads 504. The through vias 509 may include a conductive plug and a barrier film surrounding the conductive plug. The conductive plug may be or include a metal, for example, tungsten (W), titanium (Ti), aluminum (AL), or copper (Cu). The conductive plug may be formed by a plating process, a PVD process, or a CVD process. The barrier film may be or include an insulating barrier film and/or a conductive barrier film. The insulating barrier film may be formed of an oxide film, a nitride film, a carbide film, a polymer, or a combination thereof. The conductive barrier film may be disposed between the insulating barrier film and the conductive plug. The conductive barrier film may be or include a metal compound, such as, for example, tungsten nitride (WN), titanium nitride (TiN), or tantalum nitride (TaN). The barrier film may be formed by a PVD process or a CVD process.

Connection bumps 506 may be disposed below the first semiconductor chip 500a and between the first semiconductor chip 500a and the second semiconductor chip 500b. The connection bumps 506 may have a form in which a pillar (or under-bump metal) and a ball are combined. The pillar may be or include copper (Cu) or an alloy of copper (Cu), and the ball may be or include a low melting point metal, for example, tin (Sn) or an alloy including tin (Sn) (Sn—Ag—Cu). According to some example embodiments, the connection bumps 506 may be either a pillar or a ball.

An adhesive layer AF5 surrounding the connection bumps 506 may be disposed between the first semiconductor chip 500a and the second semiconductor chip 500b. The adhesive layer AF5 may affix or fasten the second semiconductor chip 500b to the first semiconductor chip 500a. The adhesive layer AF5 may be disposed between a lower surface of the second semiconductor chip 500b and an upper surface of the first semiconductor chip 500a. The adhesive layer AF5 may be same as or similar to adhesive layers AL described with reference to FIGS. 1 to 4C, and a detailed description thereof is omitted herein.

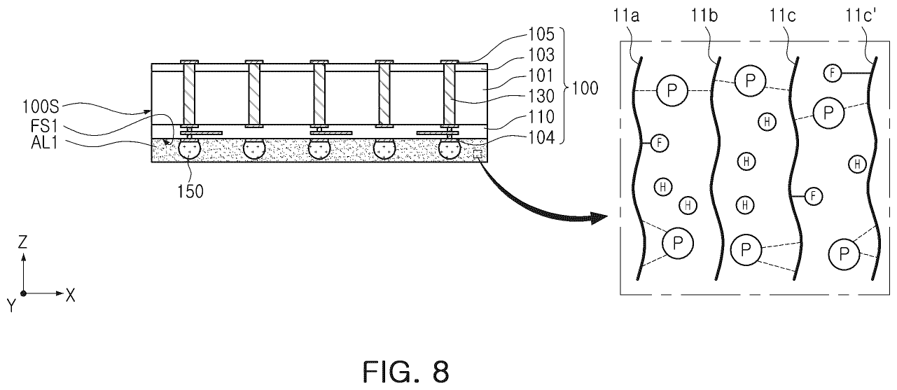

FIGS. 8 to 13 are cross-sectional views illustrating operations/processes on a method of manufacturing a semiconductor package according to some example embodiments. It is understood that additional operations/processes can be provided before, during, and after the operations in FIGS. 8 to 13, and some of the operations/processes described below can be replaced or eliminated, for additional embodiments of the method. The order of the operations/processes may be interchangeable, or two or more operations/processes can be performed simultaneously.

Referring to FIG. 8, a first adhesive layer AL1 surrounding bump structures 150 may be formed on a first front surface FS1 of a first semiconductor chip 100.

The first semiconductor chip 100 having a first substrate 101, a first device layer 110, a first back surface protective layer 103, first through vias 130 penetrating the first substrate 101 and the first back surface protective layer 103, and the first front pads 104 and the first back pads 105 may be provided. The bump structures 150 may be formed on the first front pads 104. Thereafter, the first adhesive layer AL1 may be formed to surround the bump structures 150 on the first front surface FS1 of the first semiconductor chip 100.

The first adhesive layer AL may be provided by preparing and mixing an epoxy resin 11 having a functional group F, a photosensitive compound P, and a curing agent H. By mixing the epoxy resin and a hydrophilic monomer at an appropriate ratio, the epoxy resin 11 having hydrophilic group F may be provided. The hydrophilic monomer may include at least one of polyethylene glycol, acrylic acid, and ethanol amine, but example embodiments are not limited thereto. By mixing the photosensitive compound P with the epoxy resin 11 at an appropriate ratio, the photosensitive compound P mixed in the epoxy resin 11 may be provided. The photosensitive compound P may be physically or non-chemically coupled to backbones 11a, 11b, 11c, and 11c′ of the epoxy resin 11. The photosensitive compound P may include diazonaphthoquinone (DNQ), but example embodiments are not limited thereto. Thereafter, the curing agent H may be mixed such that the first adhesive layer AL may be provided, and the curing agent H may be physically mixed with the epoxy resin 11. The curing agent H may include ionic materials (e.g., ionic liquid), for example, as described with reference to FIG. 3.

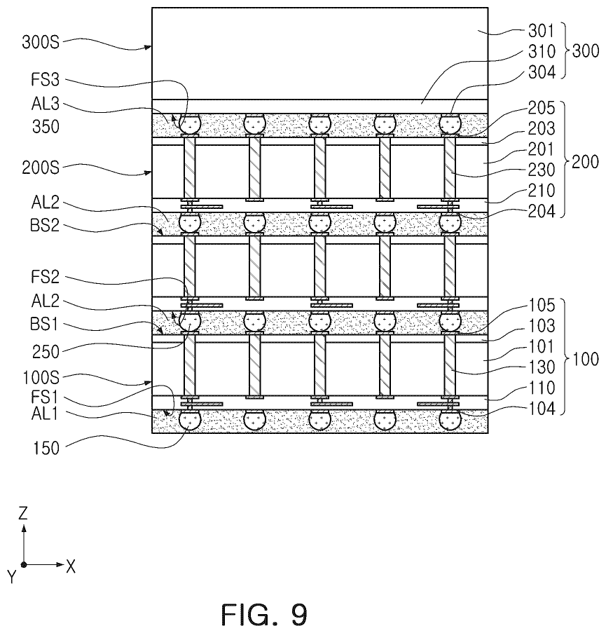

Referring to FIG. 9, second adhesive layers AL2 surrounding the second bump structures 250 may be formed on each of the second front surfaces FS2 of the plurality of second semiconductor chips 200, and third adhesive layers AL3 surrounding the bump structures 350 may be formed on the third front surface FS3 of the third semiconductor chip 300. Thereafter, the plurality of second semiconductor chips 200 having the second adhesive layer AL2 attached thereto may be formed in order on a first back surface BS1 of the first semiconductor chip 100, and a third semiconductor chip 300 having a third adhesive layer AL3 attached thereto may be formed on a second back surface BS2 of an uppermost side of the second semiconductor chip 200.

Similar to the example described with reference to FIG. 8, the plurality of second semiconductor chips 200 including a second substrate 201, a second device layer 210, a second back surface protective layer 203, second through vias 230 penetrating the second substrate 201 and the second back surface protective layer 203, and the second front-surface pads 204 and the second back-surface pads 205 may be provided. Thereafter, the second adhesive layer AL2 may be formed on the first front surface FS2 of the third semiconductor chip 300 to surround the second bump structures 250.

Similarly, the third semiconductor chips 300 including a third substrate 301, a third device layer 310, and third front-surface pads 304 may be provided. Thereafter, the third adhesive layer AL3 may be formed on the third front surface FS3 of the third semiconductor chip 300 to surround the bump structures 350.

Thereafter, the plurality of second semiconductor chips 200 including the second adhesive layer AL2 attached thereto may be formed in order on the first back surface BS1 of the first semiconductor chip 100.

Thereafter, the third semiconductor chip 300 having the third adhesive layer AL3 attached thereto may be formed on the second back surface BS2 of the uppermost side of the second semiconductor chip 200.

Referring to FIG. 10, the first semiconductor chip 100, the plurality of second semiconductor chips 200, and the third semiconductor chip 300 stacked in order may be mounted on the base chip 400. Here, the first semiconductor chip 100, the plurality of second semiconductor chips 200, and the third semiconductor chip 300 stacked in order may be referred to as a chip stack or a stacked structure. Thereafter, the chip stack may be thermal compression bonded at the first temperature.

The base chip 400 may be temporarily attached to a carrier 30 by an adhesive material layer 31. The base chip 400 may include a substrate 401, a device layer 410, an upper protective layer 403, through-electrodes 430 penetrating the substrate 401 and the upper protective layer 403, and upper and lower pads 405 and 404. The adhesive material layer 31 may be provided to surround the connection bumps 450 on a lower surface LS of the base chip 400.

The chip stack may be placed on the base chip 400, and thereafter, thermal compression bonding may be performed. The thermal compression bonding may be performed at a first temperature (for example, a melting point of the bump structures 150, 250 and/or 350).

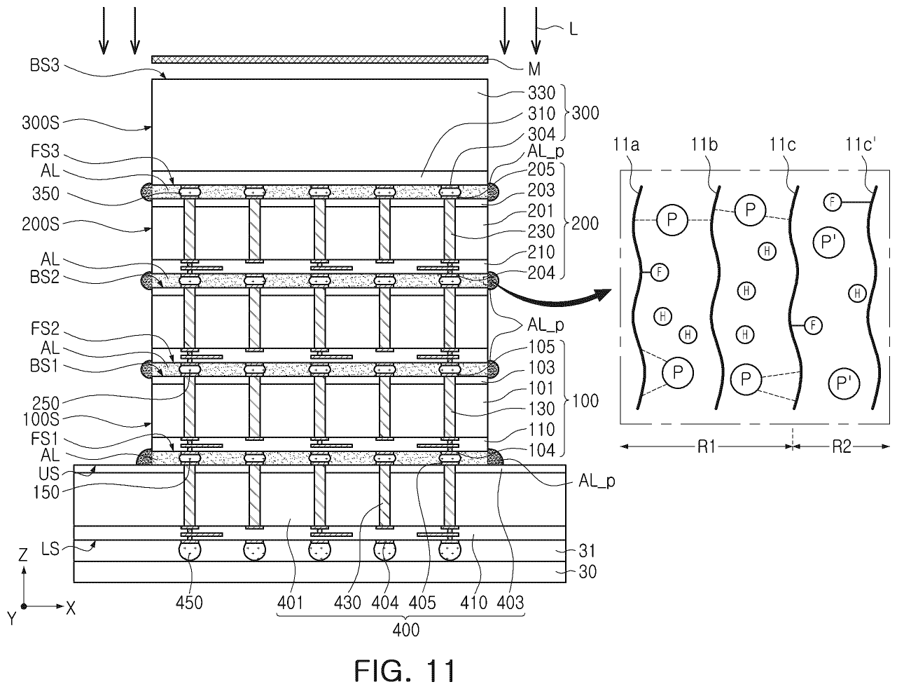

In the first region R1, a plurality of bump structures 150, 250, and 350 may be pressed at the first temperature and may be adhered or fastened to the adjacent pads 405, 105 and 205. Here, the first region R1 may be defined as a region in which the adhesive layers AL may completely overlap the plurality of semiconductor chips 100, 200, and 300. In some example embodiments, the first region R1 may be defined as a region not exposed to ultraviolet light (see FIG. 11). The curing temperature (or “second temperature”) of the adhesive layers AL may be higher than the first temperature. Accordingly, the adhesive layers AL may not be cured in the thermal compression bonding process. The first temperature may be lower than 250° C. (or about 250° C.). The first temperature may range, for example, from 150° C. (or about 150° C.) to 250° C. (or about 250° C.).

In the second region R2, the plurality of fillet portions AL_p protruding outwardly than the side surfaces 100S, 200S, and 300S of the semiconductor chips 100, 200, and 300 may be formed. Here, the second region R2 may be defined as a region in which the adhesive layers AL may protrude from the side surfaces 100S, 200S, and 300S of the plurality of semiconductor chips 100, 200, and 300. In some example embodiments, the second region R2 may be defined as a region exposed to ultraviolet light. (see FIG. 11).

Referring to FIG. 11, a mask M may be disposed or positioned over the chip stack and may be exposed to a beam of light L. Solubility of the plurality of fillet portions AL_p may change due to the beam of light L.

The beam of light L may be ultraviolet light. The photosensitive compound P′ of which a chemical structure is changed may be formed in the second region R2 due to the beam of light L, and bonding between the photosensitive compound P and backbones (e.g., 11c and 11c′) may be broken. Accordingly, solubility of the adhesive layers AL2 of the first region R1 and solubility of the plurality of fillet portions AL_p of the second region R2 may be different. For example, solubility of the plurality of fillet portions AL_p of the second region R2 may be higher than solubility of the adhesive layers AL2 of the first region R1.

The second region R2 may be different from a horizontal width of each of the plurality of fillet portions AL_p. The second region R2 may be larger than a horizontal width of each of the plurality of fillet portions AL_p. At least a portion of the second region R2 may be formed more inwardly than the side surfaces 100S, 200S, and 300S of the plurality of semiconductor chips 100, 200, and 300 (see FIGS. 4A to 4C), for example.

Referring to FIG. 12, the plurality of fillet portions AL_p may be removed.

The plurality of fillet portions AL_p of the second region (“R2” in FIG. 11) may be removed by the developer. The plurality of fillet portions AL_p may be removed by the developer combined with the hydrophilic group F of the second region (“R2” in FIG. 11). Accordingly, the side surfaces 100S, 200S, and 300S of the adhesive layers AL and the plurality of semiconductor chips 100, 200, and 300 may be aligned or flushed.

In some example embodiments, the side surfaces 100S, 200S, and 300S of the adhesive layers AL and the plurality of semiconductor chips 100, 200, and 300 may not be aligned. The side surface ALS of at least a portion of the adhesive layers AL may have a more inwardly curved surface than the side surfaces 100S, 200S, and 300S of the plurality of semiconductor chips 100, 200, and 300 (see FIG. 4A), for example. The side surface ALS of at least a portion of the adhesive layers AL may have an inclined curved surface with respect to the back surfaces BS1 and BS2 of the semiconductor chips (e.g., 100, 200) or the upper surface US of the base chip 400 (see FIG. 4B), or may have a planar inclined surface (see FIG. 4C).

Referring to FIG. 13, the adhesive layers AL may be cured by the curing agent H at a second temperature.

The adhesive layers AL may be crosslinked by the curing agent H at the second temperature. The second temperature may be defined by the curing temperature of the adhesive layers AL. The curing agent H may include an ionic material.

At the second temperature, the positive ion of the ionic material may function as an initiator in the crosslinking process. A portion of positive ion initiators may directly react with the polymer backbones 11a, 11b, 11c, 11d, and 11e and may form chemical bonds during the curing process (“H1” in FIG. 13). A portion of ionic materials may function as physical crosslinkers in the polymer matrix (“H2” in FIG. 13). A portion of the positive ion initiators may function as catalysts to promote ring-opening polymerization of epoxy groups and to form crosslinking between the polymer backbones 11a, 11b, 11c, 11d, and 11e (“H3” in FIG. 13). Accordingly, the adhesive layers AL may be defined as including a positive photosensitive epoxy resin composition.

The second temperature may be higher than the first temperature. The second temperature may be higher than 250° C. (or about 250° C.). For example, the second temperature may range from 250° C. (or about 250° C.) to 300° C. (or about 300° C.).

According to some example embodiments, the semiconductor package and the method of manufacturing the same having an adhesive layer including a photosensitive compound may be provided.

According to some example embodiments, by including an adhesive layer including a photosensitive compound having a positive photosensitive insulating resin composition including a photosensitive compound, a fillet portion protruding from a side surface of a semiconductor chip to an outer side may be reduced or minimized, such that a semiconductor package having improved reliability may be provided.

While several example embodiments have been provided in the present disclosure, it should be understood that the disclosed systems and methods might be embodied in many other specific forms without departing from the spirit or scope of the present disclosure. The present examples embodiments are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various example embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A semiconductor package, comprising:
a base chip;
a first semiconductor chip on the base chip;
first bump structures between the base chip and the first semiconductor chip, and the first bump structures electrically connecting the base chip and the first semiconductor chip;
a plurality of second semiconductor chips sequentially stacked on the first semiconductor chip;
second bump structures between adjacent second semiconductor chips of the plurality of second semiconductor chips, and the second bump structures electrically connecting the adjacent second semiconductor chips to each other; and
adhesive layers comprising a first adhesive layer surrounding the first bump structures between the base chip and the first semiconductor chip and second adhesive layers surrounding the second bump structures between the plurality of second semiconductor chips,
wherein the adhesive layers have a width equal to or less than a width of the first semiconductor chip and a width of each of the plurality of second semiconductor chips in a direction parallel to an upper surface of the base chip, and
wherein at least one of the adhesive layers comprises a positive photosensitive epoxy resin composition comprising a photosensitive compound.

2. The semiconductor package of claim 1, wherein the photosensitive compound comprises at least one of an azo compound or a diazide compound.

3. The semiconductor package of claim 1, wherein the photosensitive compound comprises at least one of a diazo quinone compound or a quinone diazide compound.

4. The semiconductor package of claim 1, wherein the photosensitive compound comprises at least one of diazonaphthoquinone, benzoquinone diazide, naphthoquinone diazide or a derivative thereof.

5. The semiconductor package of claim 1, wherein at least a portion of at least one of the adhesive layers has an inwardly concave curved surface.

6. The semiconductor package of claim 1, wherein at least a portion of at least one of the adhesive layers has a width increasing toward the base chip.

7. The semiconductor package of claim 6, wherein a side surface of the at least a portion of the at least one of the adhesive layers has a curved inclined surface.

8. The semiconductor package of claim 6, wherein a side surface of the at least a portion of the at least one of the adhesive layers has a planar inclined surface.

9. The semiconductor package of claim 1, further comprising:
a third semiconductor chip on the plurality of second semiconductor chips; and
third bump structures between an uppermost second semiconductor chip of the plurality of second semiconductor chips and the third semiconductor chip, and the third bump structures electrically connecting the uppermost second semiconductor chip and the third semiconductor chip,
wherein the adhesive layers are between the uppermost second semiconductor chip and the third semiconductor chip and further comprise a third adhesive layer surrounding the third bump structures.

10. The semiconductor package of claim 9, wherein the third adhesive layer has a width equal to or less than a width of the first semiconductor chip, a width of each of the plurality of second semiconductor chips, and a width of the third semiconductor chip in a direction parallel to an upper surface of the base chip.

11. The semiconductor package of claim 9, wherein the third semiconductor chip has a thickness greater than a thickness of the first semiconductor chip and a thickness of each of the plurality of second semiconductor chips.

12. The semiconductor package of claim 1, wherein the base chip has a width greater than a width of the first semiconductor chip and a width of each of the plurality of second semiconductor chips in a direction parallel to an upper surface of the base chip.

13. The semiconductor package of claim 1, further comprising:
an encapsulant covering the first semiconductor chip, the plurality of second semiconductor chips, and the adhesive layers on the base chip.

14. A semiconductor package, comprising:
a base chip;
a plurality of semiconductor chips sequentially stacked on the base chip;
bump structures between the base chip and a lowermost semiconductor chip of the plurality of semiconductor chips, and between the plurality of semiconductor chips; and
adhesive layers surrounding the bump structures between the base chip and the lowermost semiconductor chip of the plurality of semiconductor chips and between the plurality of semiconductor chips,
wherein the adhesive layers have a width equal to or less than a width of each of the plurality of semiconductor chips in a direction parallel to an upper surface of the base chip, and
wherein at least one of the adhesive layers comprises,
a polymer resin having a hydrophilic group;
a photosensitive compound physically bonded to the polymer resin; and
an ionic material crosslinking the polymer resin.

15. The semiconductor package of claim 14, wherein the hydrophilic group comprises at least one of a hydroxyl group, a carboxyl group, or an amine group.

16. The semiconductor package of claim 14, wherein the ionic material includes at least one of 1-butyl-3-methylimidazolium tetrafluoroborate, 1-ethyl-3-methylimidazolium dicyanamide, 1-butyl-3-methylimidazolium tetrafluorophosphate, 1,3-dioctadecyl-methylimidazolium iodide, 1-aminopropyl-3-butylimidazolium bis(trifluoromethanesulfonyl)imide, tetrabutylammonium leucine, or trihexyltetradecylphosphonium ethylhexanoyl.

17. The semiconductor package of claim 14, wherein a thickness of each of the adhesive layers is 1 μm to 50 μm.

18. A semiconductor package, comprising:
a base chip;
a first semiconductor chip on the base chip;
first bump structures electrically connecting the base chip and the first semiconductor chip;
first adhesive layers surrounding the first bump structures below the first semiconductor chip;
a second semiconductor chip on the first semiconductor chip;
second bump structures electrically connecting the first semiconductor chip and the second semiconductor chip;
second adhesive layers surrounding the second bump structures below the second semiconductor chip; and
an encapsulant covering side surfaces of the first and second semiconductor chips and side surfaces of the first and second adhesive layers on the base chip,
wherein the side surfaces of the first and second semiconductor chips and side surfaces of the first and second adhesive layers are on a same plane,
wherein the first and second adhesive layers comprise a polymer resin, a photosensitive compound, and a curing agent, and
wherein a curing temperature of each of the first and second adhesive layers has a melting point higher than a melting point of each of the first and second bump structures.

19. The semiconductor package of claim 18,
wherein the curing temperature of each of the first and second adhesive layers is 250° C. or higher, and
wherein the melting point of each of the first and second bump structures is 250° C. or lower.

20. The semiconductor package of claim 18, further comprising:
a third semiconductor chip on the second semiconductor chip, and the third semiconductor chip having a side surface covered by the encapsulant; and
third bump structures electrically connecting the second semiconductor chip and the third semiconductor chip; and
a third adhesive layer surrounding the third bump structures below the third semiconductor chip,
wherein a side surface of the third adhesive layer is aligned with the side surfaces of the first, second and third semiconductor chips, and the side surfaces of the first and second adhesive layers.
